(19) United States
(12) Patent Application Publication
(10) Pub. No.: US 2014/0174522 A1
(43) Pub. Date: Jun. 26, 2014

(54) Solar Cell

(71) Applicant: SOLARTECH ENERGY CORP., Taoyuan (TW)

(72) Inventors: Di-Wei Yang, Taoyuan (TW); Yu-Wei Kuo, Taoyuan (TW); Chung-Wen Lan, Taoyuan (TW)

(73) Assignee: SOLARTECH ENERGY CORP., Taoyuan (TW)

(21) Appl. No.: 13/833,266

(22) Filed: Mar. 15, 2013

(30) Foreign Application Priority Data
Dec. 25, 2012 (TW) 101225022
Dec. 25, 2012 (TW) 101225023

(51) Int. Cl. H01L 31/0224

(52) U.S. Cl. CPC H01L 31/022433
USPC 136/256

(57) ABSTRACT

An embodiment of the present invention provides a solar cell. The solar cell includes a semiconductor substrate, a plurality of finger electrodes, and a plurality of bus electrodes. The finger electrodes are disposed on a surface of the semiconductor substrate. The bus electrodes are disposed on the surface of the semiconductor substrate separately. At least one of the bus electrodes includes a plurality of branch electrodes, and the branch electrodes are disposed on the surface of the semiconductor substrate in parallel. An outer side of each of the branch electrodes is connected to at least one of the finger electrodes. This embodiment may help reduce the cost for manufacturing the solar cell.

### CROSS-REFERENCE TO RELATED APPLICATIONS

This application claims the priority benefits of Taiwan Patent Application Serial No. 101225022, filed on Dec. 25, 2012, and Taiwan Patent Application Serial No. 101225023, filed on Dec. 25, 2012. The entirety of the above-mentioned patent applications is incorporated by reference herein and made a part of specification.

### BACKGROUND

1. Technical Field

The invention relates generally to solar cells, and more particularly, to bus electrodes of solar cells.

2. Related Art

Existing minerals that may be used to generate electricity, such as crude oil and coal, are being exhausted. Furthermore, thermal power plants have been exacerbating global warming. As a result, it is critical for the human beings to develop and promote alternative energy that is sustainable. Among all potential sources of sustainable alternative energy, solar energy is a kind that's relatively more popular.

Generally speaking, a solar cell has a semiconductor substrate and a p-n junction formed on the semiconductor substrate. When the p-n junction is illuminated, the solar cell may generate electric current. The solar cell has bus electrodes on a light-receiving surface and an opposite surface for outputting electric voltage and current. Generally speaking, when manufacturing solar cells, silver paste is used to print the bus electrodes on the light-receiving surface. The amount of silver paste used critically affects the overall manufacturing costs.

Accordingly, new bus electrodes that can not only maintain the solar cells' overall performance but also reduce the required amount of silver paste will be quite valuable.

### BRIEF SUMMARY

One of the objectives of the invention is to reduce the amount of silver paste required in manufacturing solar cells.

An embodiment of the invention provides a solar cell. The solar cell includes a semiconductor substrate, a plurality of finger electrodes, and a plurality of bus electrodes. The finger electrodes are disposed on a surface of the semiconductor substrate. The bus electrodes are separately disposed on the surface. At least one of the bus electrodes includes a plurality of branch electrodes, which are disposed on the surface in parallel. An outer side of each of the branch electrodes is electronically connected to at least one of the finger electrodes.

Another embodiment of the invention provides a solar cell. The solar cell includes a semiconductor substrate, a plurality of finger electrodes, and a plurality of bus electrodes. The finger electrodes are disposed on a surface of the semiconductor substrate. The bus electrodes are separately disposed on the surface. At least one of the bus electrodes includes a plurality of conducting blocks, which are independent from each other. The conducting blocks are disposed along a first direction on the surface. Each of the conducting blocks is electronically connected to at least one of the finger electrodes.

Other features of the present invention will be apparent from the accompanying drawings and from the detailed description which follows.

### BRIEF DESCRIPTION OF THE DRAWINGS

The invention is fully illustrated by the subsequent detailed description and the accompanying drawings, in which like references indicate similar elements.

FIG. 1 shows a top view of a solar cell according to an embodiment of the invention.

FIG. 2-6 shows partial schematic diagrams of solar cells according to several embodiments of the invention.

FIG. 7 shows a top view of a solar cell according to an embodiment of the invention.

FIG. 8-12 shows partial schematic diagrams of solar cells according to several embodiments of the invention.

### DETAILED DESCRIPTION

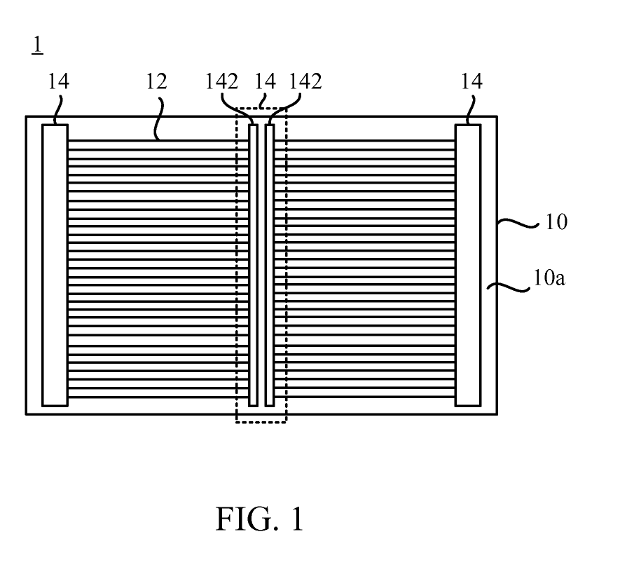

Please refer to FIG. 1, which shows a top view of a solar cell according to an embodiment of the invention. The solar cell 1 of this embodiment has a semiconductor substrate 10, a plurality of finger electrodes 12, and a plurality of bus electrodes 14. The finger electrodes 12 and the bus electrodes 14 are disposed on a surface 10a of the semiconductor substrate 10 through screen printing or another appropriate method. Generally speaking, the surface 10a will serve as a light-receiving surface of the solar cell 1, and the semiconductor substrate 10 should have a p-n junction underneath the surface 10a. As a result, when the surface 10a of the semiconductor substrate 10 is illuminated, especially by the Sun, the solar cell 1 may output voltage and current.

Although the finger electrodes 12 of this embodiment are disposed parallel on the surface 10a, finger electrodes of other embodiments may have shapes and arrangements different from that depicted in FIG. 1. For example, a finger electrode needs not to be like a line, but may alternatively be like an uneven triangle, diamond, polygon, or another shape with curves. In addition, finger electrodes need not be parallel to each other; alternatively, they may interlace with each other or not parallel to each other. Each finger electrode should be electronically connected to at least one bus electrode. In addition, the width of the bus electrodes 14 is not limited and the bus electrodes 14 may have the same or different widths and shapes.

At least one of the bus electrodes 14 separately disposed on the surface 10a has at least two branch electrodes 142. For example, any two bus electrodes 14, whether they have branch electrodes 142 or not, may be parallel to each other. In other words, a bus electrode 14 with no branch electrode 142 is a substantial electrode and generally extends along a specific direction (e.g. the vertical direction on FIG. 1). On the other hand, a bus electrode 14 with at least two branch electrodes 142 is in fact a combination of the branch electrodes 142. Each of the branch electrodes 142 generally also extends along the specific direction (e.g. the vertical direction on FIG. 1).

Although only two branch electrodes 142 are depicted in FIG. 1, a solar cell of another embodiment may have more than two branch electrodes. The branch electrodes 142 of a bus electrode 14 are not electronically connected to each other originally, but may be electronically connected to each other after further processing, such as after a conducting stripe is soldered thereon.

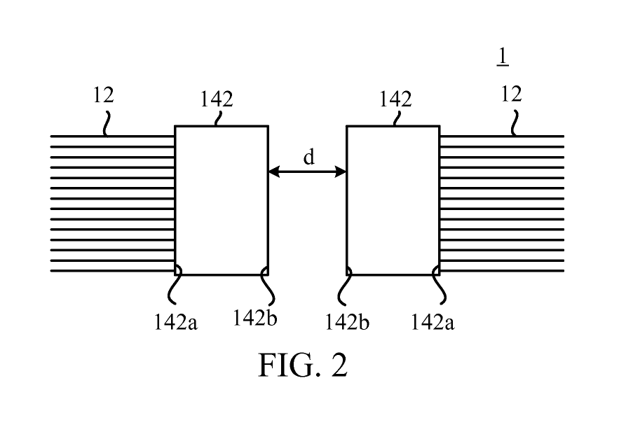

Please refer to FIG. 1 and FIG. 2. FIG. 2 shows a partial schematic diagram of the solar cell 1 of FIG. 1 according to an embodiment of the invention. As FIG. 2 shows, the finger electrodes 12 are electronically connected to the outer sides 142a of the branch electrodes 142. In addition, there is a predetermined distance d between the inner sides 142b of the branch electrodes 142. For example, the predetermined distance d is greater than 0 mm and less than 2 mm. In other words, the two adjacent branch electrodes 142 may be electrically isolated from each other and less than 2 mm apart from each other.

The width of each of the branch electrodes 142 is not limited. All the branch electrodes 142 may have the same width or not. Two outer sides 142a of two branch electrodes 142 that not only belong to the same bus electrode 14 but also are furthest from each other may have a specific distance. For example, the specific distance may be the same as the width of a bus electrode 14 that contains no branch electrode 142.

Although the branch electrodes 142 of FIGS. 1 and 2 are shaped like stripes, branch electrodes of another embodiment may be shaped like uneven triangles, diamonds, polygons, or other shapes with curves. Within a solar cell, all the branch electrodes may have substantially the same shape.

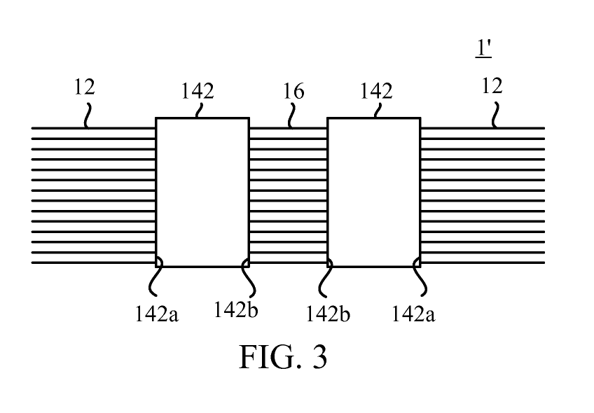

FIG. 3 shows an embodiment that's modified based on the embodiment shown in FIG. 2. The embodiments of FIG. 2 and FIG. 3 are different mainly in that the solar cell l′ of FIG. 3 further includes redundant electrodes 16 between two adjacent branch electrodes 142.

The finger electrodes 12 may pass underneath two branch electrodes 142. The parts of these finger electrodes 12 lying between two adjacent branch electrodes 142, i.e. interconnecting the two inner sides 142b of the two adjacent branch electrodes 142, may be referred to as the redundant electrodes 16. In other words, those outside the outer sides 142a of the branch electrodes 142 are referred to as finger electrodes 12. As an example, the redundant electrodes 16 may be disposed on the extension directions of the finger electrodes 12.

The finger electrodes 12, the branch electrodes 142, and the redundant electrodes 16 may all be printed on the semiconductor substrate 10. Therefore, the phrase “pass underneath” used in the previous paragraph may not be the fact but is used only to help understand the spatial relationship between the finger electrodes 12 and the redundant electrodes 16. Of course, the redundant electrodes 16 need not to connect two branch electrodes 142, and need not to extend from the inner sides 142b of the branch electrodes 142.

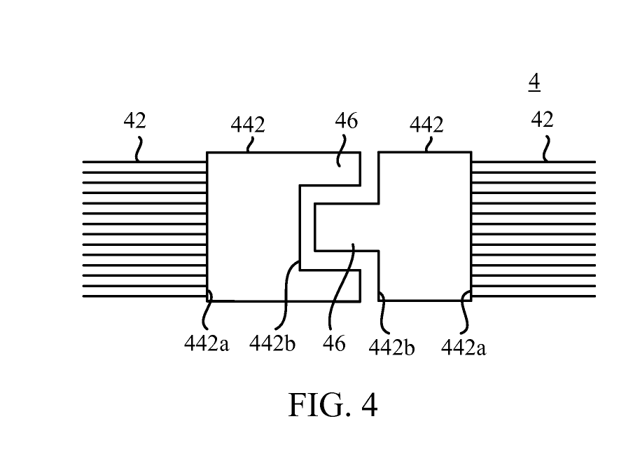

Please refer to FIG. 4, which shows a partial schematic diagram of a solar cell according to an embodiment of the invention. The solar cell 4 of this embodiment has a semiconductor substrate (which is not labeled in the figure), a plurality of finger electrodes 42, a plurality of branch electrodes 442, and a plurality of redundant electrodes 46. Similar to the embodiment of FIG. 2, the finger electrodes 42 and the branch electrodes 442 are disposed on the semiconductor substrate, and multiple branch electrodes 442 in combination may be viewed as a bus electrode (which is not labeled in the figure). In addition, the finger electrodes 42 are electronically connected to the outer sides 442a of the branch electrodes 442. Unlike the embodiment of FIG. 2, each redundant electrode 46 is electronically connected to a branch electrode 442, making the branch electrode 442 and the redundant electrode 46 have a flexible overall shape.

In terms of function, the redundant electrodes 46 generally are not used to electronically connect the finger electrodes 42, but to make it easier to further process the solar cell 4. For example, a conducting stripe may need to be soldered on each bus electrode. If the branch electrodes of the bus electrode have small square measures, the conducting stripe may fail to adhere thereon successfully. As a result, for better and more firmly soldering the conducting stripe, the redundant electrodes 46 may be disposed on the semiconductor substrate selectively in order to meet the actual needs.

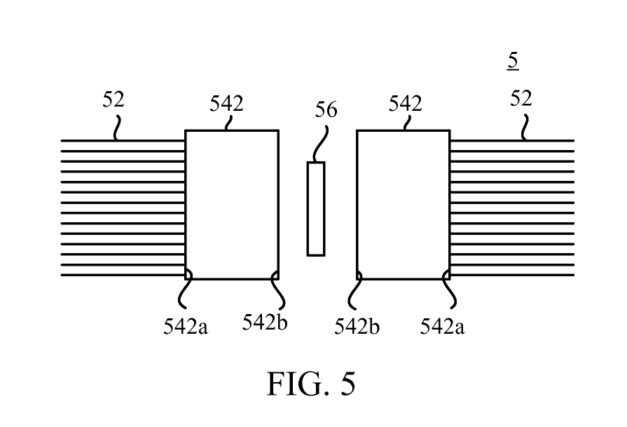

Please refer to FIG. 5. FIG. 5 shows a partial schematic diagram of a solar cell according to another embodiment of the invention. The solar cell 5 of this embodiment has a semiconductor substrate (which is not labeled in the figure), a plurality of finger electrodes 52, a plurality of branch electrodes 542, and a t least one redundant electrode 56. Similar to the embodiment of FIG. 4, the finger electrodes 52, the branch electrodes 542, and the redundant electrodes 56 are disposed on the semiconductor substrate, and a plurality of the branch electrodes 542 in combination may be viewed as a bus electrode (which is not labeled in the figure). In addition, the finger electrodes 52 are electronically connected to the outer sides 542a of the branch electrodes 542. Unlike the embodiment of FIG. 4, the redundant electrode 56 is not electronically connected to any of the branch electrodes 542.

Similar to the previous example, the redundant electrode 56 generally is not used to electronically connect to the finger electrodes 52, but to make it easier to further process the solar cell 5. As long as the existence of the redundant electrode 56 may make it easier to further process the solar cell 5, such as soldering a conducting stripe thereon, the location and shape of the redundant electrode 56 are not limited. For example, the redundant electrode 56 may be disposed between the inner sides 542b of two adjacent branch electrodes 542.

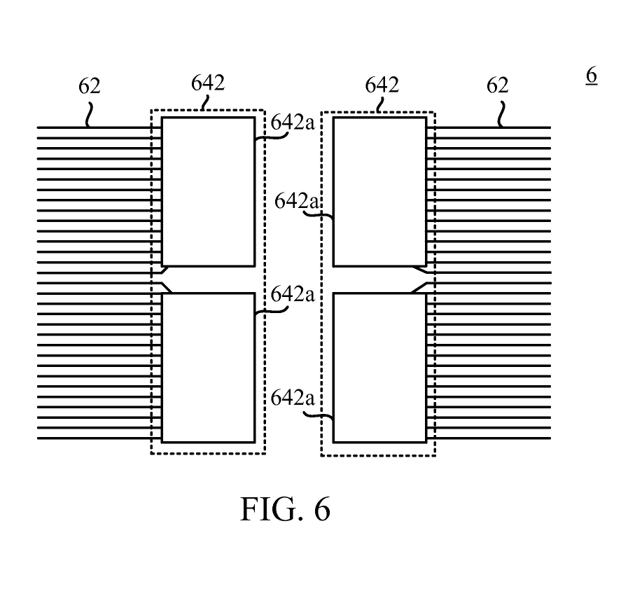

In another embodiment, a branch electrode may further include a plurality of conducting blocks. The conducting block may be independent from each other, and disposed along a specific direction one after another on the surface of a semiconductor substrate. Please refer to FIG. 6, which shows a partial schematic diagram of a solar cell according to the embodiment. The solar cell 6 of this embodiment has a semiconductor substrate (which is not labeled in the figure), a plurality of finger electrodes 62, and a plurality of branch electrodes 642. Similar to the embodiment of FIG. 2, the finger electrodes 62 and the branch electrodes 642 are disposed on the semiconductor substrate, and multiple of the branch electrodes 642 in combination may be viewed as a bus electrode (which is not labeled in the figure).

Unlike the embodiment of FIG. 2, each of the branch electrodes 642 includes a plurality of conducting blocks 642a lining up one after another. Each of the branch electrodes 642 may be viewed as multiple conducting blocks 642a in combination, and the lining up direction of those conducting blocks 642a is an extension direction of the branch electrode 642. The conducting blocks 642a are not electronically connected to each other, but may become so only after further processing, such as after soldering of a conducting stripe thereon. As long as multiple conducting blocks 642a are disposed in line and in combination constitute a branch electrode 642, the conducting blocks 642a are not limited to be shaped like rectangles.

In the solar cell of any of the aforementioned embodiments, a bus electrode is divided into a plurality of branch electrodes that are separate from each other. This arrangement nether affects the solar cell's overall performance, nor affects the subsequent process of soldering conducting stripes on bus electrodes. One of the advantages of these embodiments is that they allow the required amount of silver paste to be reduced. In other words, the embodiments may reduce the overall manufacturing costs of solar cells.

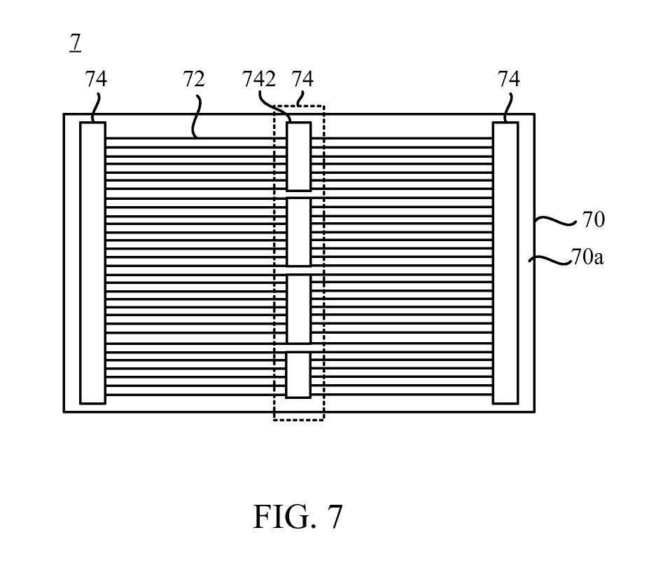

Please refer to FIG. 7, which shows a top view of a solar cell according to an embodiment of the invention. The solar cell 7 of this embodiment has a semiconductor substrate 70, a plurality of finger electrodes 72, and a plurality of bus electrodes 74. The finger electrodes 72 and the bus electrodes 74 may be disposed on a surface 70a of the semiconductor substrate 70 through printing or another proper method. Generally speaking, the surface 70a will serve as a light-receiving surface of the solar cell 7, and the semiconductor substrate 70 may have a p-n junction near the surface 70a. When the surface 70a of the semiconductor substrate 70 is illuminated, the solar cell 7 may output voltage and current.

The finger electrodes 72 are not limited to be parallel lines. Alternatively, each of them may be like an uneven triangle, diamond, polygon, or another shape with curves. In addition, they needs not be parallel to each other; alternatively, they may interlace with each other or not parallel to each other. However, each of them should be electronically connected to at least one bus electrode 74. In addition, the width of the bus electrodes 74 is not limited and the bus electrodes 74 may have the same or different widths and shapes.

At least one of the bus electrodes 74 has at least two conducting blocks 742. The conducting blocks 742 are not limited to be like wide stripes, but may alternatively be shaped like uneven triangles, diamonds, polygons, or other shapes with curves. The conducting blocks 742 may be similar to each other in terms of shape. The conducting blocks 742 depicted in FIG. 7 are aligned close to each other so that all the finger electrodes 72 can electronically connect to at least one of the conducting blocks 742. Alternatively, the conducting blocks 742 may be arranged to an extent that some of the finger electrodes 72 may need to bend (or through other circuit design) in order to electronically connect to one of the conducting blocks 742.

In this embodiment, any two of the bus electrodes 74 ate parallel to each other, regardless of whether any of the two bus electrodes 74 contains conducting blocks 742 or not. Specifically, a bus electrode 74 that does not contain conducting blocks 742 is a substantial electrode, and generally extends along a specific direction, such as the vertical direction of FIG. 7. On the other hand, a bus electrode 74 that has at least two conducting blocks 742 is in fact a combination of those conducting blocks 742. Those conducting blocks 742 are generally also disposed along the specific direction, such as the vertical direction of FIG. 7.

For a bus electrode 74 that contains conducting blocks 742, the number of contained conducting blocks 742 is not limited. The contained conducting blocks 742 are not electrically connected to each other as originally disposed, but may electrically connect to each other after further processing (such as soldering of a conducting stripe thereon).

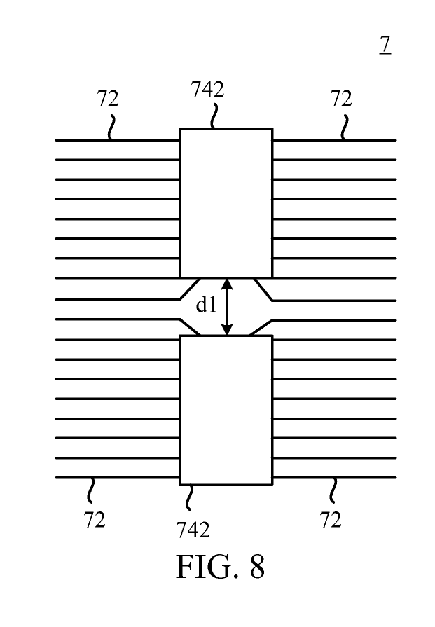

Please refer to FIG. 7 and FIG. 8. FIG. 8 shows a partial schematic diagram of the solar cell 7 of FIG. 7 according to an embodiment of the invention. The distance between two adjacent conducting blocks 742 depicted in FIG. 8 is greater than the distance between two adjacent conducting blocks 742 depicted in FIG. 7. As a result, some of the finger electrodes 72 in FIG. 8 are bent properly in order to electronically connect to a corresponding conducting block 742. As FIG. 8 shows, the finger electrodes 72 are electronically connected to the conducting blocks 742. Two adjacent conducting blocks 742 are a predetermined distance d1 apart from each other. The predetermined distance d1 may be greater than 0 mm and less than 1.5 mm. In other words, the two adjacent conducting blocks 742 are electrically isolated (separated) from each other and less than 1.5 mm apart from each other.

The width of the conducting blocks 742, along the horizontal direction of FIG. 8, is not limited. The conducting blocks 742 of the same bus electrode 74 may have the same width. The conducting blocks 742 of all different bus electrodes 74 may also have the same width. A bus electrode 74 that includes no conducting block 742 and a bus electrode 74 that includes some conducting blocks 742 may have the same width.

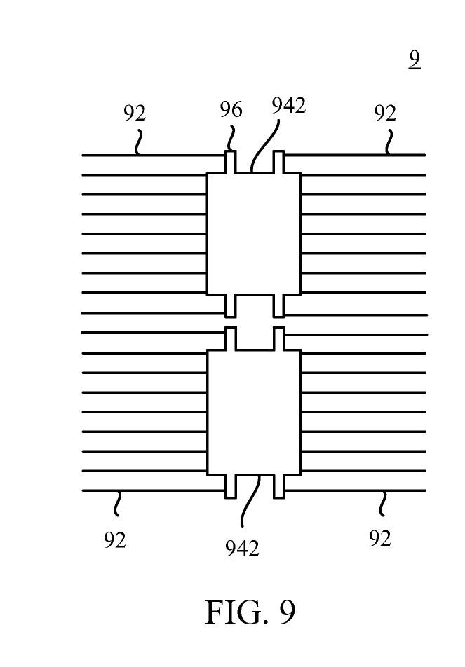

Please refer to FIG. 9, which shows a partial schematic diagram of a solar cell according to another embodiment of the invention. The solar cell 9 of this embodiment includes a semiconductor substrate (which is not labeled in the figure), a plurality of finger electrodes 92, a plurality of conducting blocks 942, and a plurality of redundant electrodes 96. Similar to the embodiment of FIG. 8, the finger electrodes 92 and the conducting blocks 942 are disposed on the semiconductor substrate. Multiple conducting blocks 942 in combination may be viewed as a bus electrode (which is not labeled in the figure). In addition, the finger electrodes 92 are electronically connected to two sides of the conducting blocks 942. Unlike the embodiment of FIG. 8, the redundant electrodes 96 are electronically connected to the conducting blocks 942, so that the conducting blocks 942 and the redundant electrodes 96 as a whole have flexible shapes.

In terms of function, the redundant electrodes 96 generally are used to electronically connect the finger electrodes 92, and to make it easier to further process the solar cell 9. For example, a conducting stripe may need to be soldered on each bus electrode. If the conducting blocks of the bus electrode have a small square measure, the conducting stripe may fail to adhere thereon successfully. As a result, for better and more firmly soldering conducting stripes, the redundant electrodes 96 may be disposed on the semiconductor substrate selectively in order to meet the actual needs.

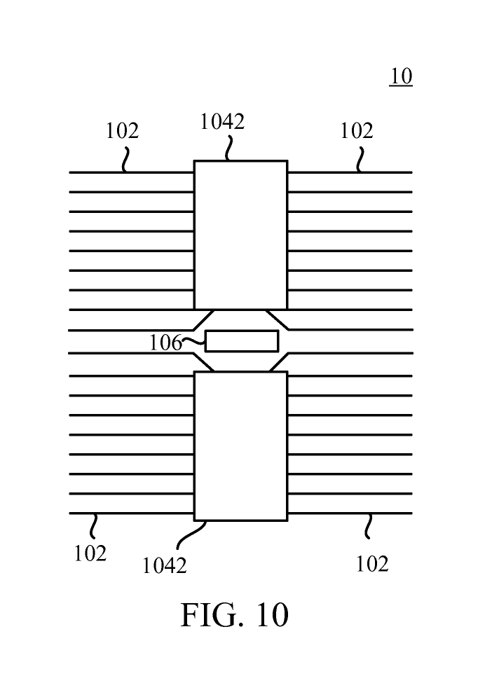

Please refer to FIG. 10, which shows a partial schematic diagram of a solar cell according to an embodiment of the invention. The solar cell 10 of this embodiment has a semiconductor substrate (which is not labeled in the figure), a plurality of finger electrodes 102, a plurality of conducting block 1042, and at least one redundant electrode 106. Similar to the embodiment of FIG. 9, the finger electrodes 102, the conducting blocks 1042, and the redundant electrode 106 are disposed on the semiconductor substrate. Multiple conducting blocks 1042 in combination may be viewed as a bus electrode (which is not labeled in the figure). In addition, the finger electrodes 102 are electronically connected to two sides of the conducting blocks 1042. Unlike the embodiment of FIG. 9, the redundant electrode 106 of this embodiment is not electronically connected to any of the conducting blocks 1042.

Unlike the redundant electrodes 96 of the previous embodiment, the redundant electrode 106 of this embodiment is generally not used to electronically connect to the finger electrodes 102. The redundant electrode 106 mainly makes it easier to further process the solar cell 10. Please note that the location and the shape of the redundant electrode 106 are not limited. For example, the redundant electrode 106 may be disposed in between two adjacent conducting blocks 1042.

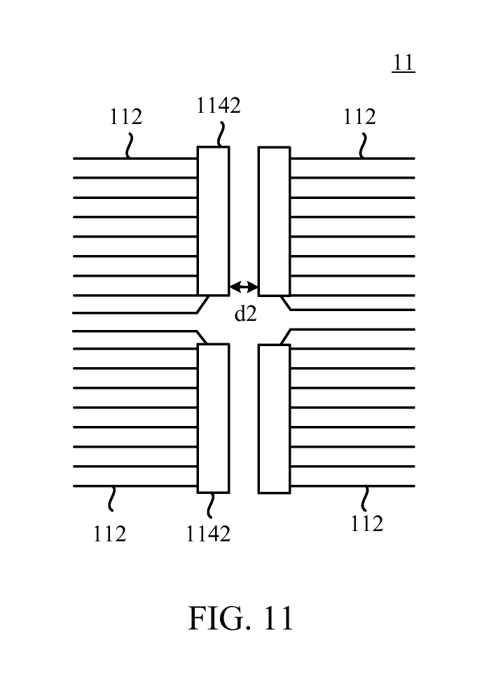

Please refer to FIG. 11, which shows a partial schematic diagram of a solar cell according to an embodiment of the invention. The solar cell 11 of this embodiment has a semiconductor substrate (which is not labeled in the figure), a plurality of finger electrodes 112, and a plurality of conducting blocks 1142. Similar to the embodiment of FIG. 8, the finger electrodes 112 and the conducting blocks 1142 are disposed on the semiconductor substrate. Multiple conducting blocks 1142 in combination may be viewed as a bus electrode (which is not labeled in the figure).

Unlike the embodiment of FIG. 8, the conducting blocks 1142 are arranged into at least two lines. Each line of conducting blocks 1142 in combination may be viewed as a branch electrode (which is not labeled in the figure). The extension direction of the branch electrode is the lining up direction of the line of conducting blocks 1142. The conducting blocks 1142 of the same line are not electronically connected to each other, nor are the conducting blocks 1142 of different lines electrically connected to each other. Only after further processing of the solar cell 11, such as the soldering of a conducting stripe there on, will two conducting blocks 1142 be electronically connected to each other. There may be a predetermined distance d2 between two adjacent lines of conducting blocks 1142. For example, the predetermined distance d2 may be greater than 0 mm and less than 2 mm.

Two opposite sides of a conducting block 1142 are not both electronically connected to finger electrodes 112. It's enough if one side of the conducting block 1142 is electronically connected to the finger electrodes 112.

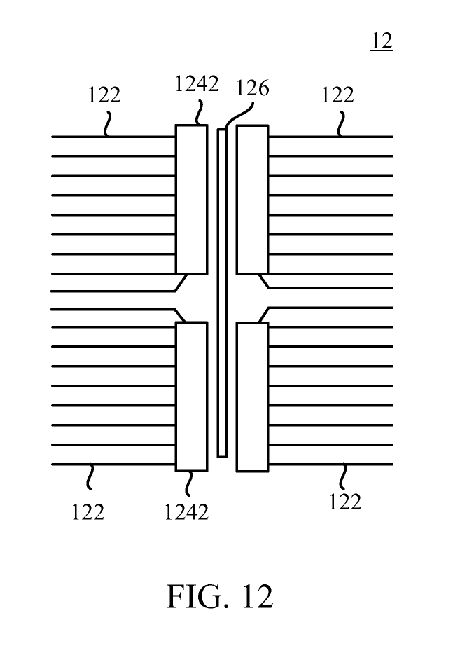

Please refer to FIG. 12, which shows a partial schematic diagram of a solar cell according to an embodiment of the invention. The solar cell 12 of this embodiment has a semiconductor substrate (which is not labeled in the figure), a plurality of finger electrodes 122, a plurality of conducting blocks 1242, and at least one redundant electrode 126. Similar to the embodiment of FIG. 11, the finger electrodes 122 and the conducting blocks 1242 are disposed on the semiconductor substrate. Multiple conducting blocks 1242 in combination may be viewed as a bus electrode (which is not labeled in the figure). Unlike the embodiment of FIG. 11, the redundant electrode 126 is disposed between two lines of adjacent conducting blocks 1242. This arrangement may make it easier to further process the solar cell 12, such as further soldering conducting stripes thereon.

In each of the solar cells of the embodiments depicted in FIG. 7 to FIG. 12, at least one bus electrode includes a plurality of conducting blocks that are separate from each other. The conducting blocks line up along a first direction. Neither will this arrangement affect the solar cell's overall performance, nor will it affect the subsequent process of soldering conducting stripes. One of the advantages of these embodiments is that they allow the required amount of silver paste to be reduced. In other words, the embodiments may reduce the overall manufacturing costs of solar cells.

In the foregoing detailed description, the invention has been described with reference to specific exemplary embodiments thereof. It will be evident that various modifications may be made thereto without departing from the spirit and scope of the invention as set forth in the following claims. The detailed description and drawings are, accordingly, to be regarded in an illustrative sense rather than a restrictive sense.

What is claimed is:

1. A solar cell, comprising:
a semiconductor substrate;
a plurality of finger electrodes, disposed on a surface of the semiconductor substrate; and
a plurality of bus electrodes, separately disposed on the surface, wherein at least one of the bus electrodes comprises a plurality of branch electrodes, the branch electrodes are disposed on the surface in parallel, and an outer side of each of the branch electrodes is electronically connected to at least one of the finger electrodes.

2. The solar cell of claim 1, wherein the branch electrodes have a same shape.

3. The solar cell of claim 1, wherein two adjacent ones of the branch electrodes are a first distance away from each other, and the first distance is greater than 0 mm and less than 2 mm.

4. The solar cell of claim 1, further comprising a redundant electrode electronically connected to at least one of the branch electrodes.

5. The solar cell of claim 1, further comprising a redundant electrode electrically isolated from the branch electrodes.

6. The solar cell of claim 5, wherein the redundant electrode is disposed between two adjacent ones of the branch electrodes.

7. The solar cell of claim 1, wherein at least one of the branch electrodes comprises a plurality of conducting blocks, the conducting blocks are independent from each other, and the conducting blocks are disposed along a first direction one after another on the surface.

8. The solar cell of claim 7, wherein the bus electrodes are parallel to each other, and the first direction is parallel to an extension direction of the bus electrodes.

9. A solar cell, comprising:
a semiconductor substrate;
a plurality of finger electrodes, disposed on a surface of the semiconductor substrate; and
a plurality of bus electrodes, separately disposed on the surface, wherein at least one of the bus electrodes comprises a plurality of conducting blocks, the conducting blocks are independent from each other, the conducting blocks are disposed along a first direction on the surface, and each of the conducting blocks is electronically connected to at least one of the finger electrodes.

10. The solar cell of claim 9, wherein the conducting blocks are disposed along the first direction one after another on the surface.

11. The solar cell of claim 10, wherein two adjacent ones of the conducting blocks are a first distance away from each other, and the first distance is greater than 0 mm and less than 1.5 mm.

12. The solar cell of claim 9, further comprising a redundant electrode electronically connected to at least one of the conducting blocks.

13. The solar cell of claim 9, further comprising a redundant electrode electrically isolated from the conducting blocks.

14. The solar cell of claim 9, wherein the conducting blocks are disposed in a plurality of rows along the first direction on the surface.

15. The solar cell of claim 14, wherein two adjacent ones of the rows are a second distance away from each other, and the second distance is greater than 0 mm and less than 2 mm.

16. The solar cell of claim 9, wherein the bus electrodes are parallel, and the first direction is parallel to an extension direction of the bus electrodes.
